(19) United States
(12) Patent Application Publication
(10) Pub. No.: US 2016/0218275 A1
(43) Pub. Date: Jul. 28, 2016

(54) ELECTROMECHANICAL TRANSDUCER COMPRISING A POLYURETHANE POLYMER WITH POLYESTER AND/OR POLYCARBONATE UNITS

(71) Applicants: Berthold JENNINGER, Gex (FR); Joachim Wagner, Koeln (DE); Sebastian Doerr, Duesseldorf (DE)

(72) Inventors: Joachim Wagner, Koeln (DE); Werner Jenninger, Koeln (DE); Sebastian Doerr, Duesseldorf (DE)

(73) Assignee: BAYER INTELLECTUAL PROPERTY GmbH, Monheim (DE)

(21) Appl. No.: 13/812,853

(22) PCT Filed: Aug. 5, 2011
(86) PCT No.: PCT/EP2011/063571

§ 371 Date: Feb. 22, 2016

(30) Foreign Application Priority Data
Aug. 9, 2010 (EP) 10172246.0
Aug. 9, 2010 (EP) 10172247.8

(51) Int. Cl. H01L 41/193; C08G 18/42; H01L 41/113; H01L 41/45; H01L 41/09; C08G 18/73; C08G 18/44

(52) U.S. Cl. CPC H01L 41/193; C08G 18/73; C08G 18/42; C08G 18/44; H01L 41/45; H01L 41/09; H01L 41/1132; H01L 41/113

(57) ABSTRACT

The present invention relates to an electromechanical transducer comprising a dielectric elastomer with contact by a first electrode and a second electrode, wherein the dielectric elastomer comprises a polyurethane polymer. In this case, the polyurethane polymer comprises at least one polyester and/or polycarbonate unit. The invention also relates to a process for producing such an electromechanical transducer, to the use of the dielectric elastomer used and also to an electrical and/or electronic apparatus comprising an electromechanical transducer according to the invention.

The present invention relates to an electromechanical converter, including a dielectric elastomer which is in contact with a first electrode and a second electrode, in which the dielectric elastomer includes a polyurethane polymer. The polyurethane polymer in this case includes at least one polyester and/or polycarbonate unit. The invention further relates to a method for producing an electromechanical converter of this kind, the use of the dielectric elastomer involved and an electrical and/or electronic device including an electromechanical converter according to the invention.

Electromechanical converters play an important part in converting electrical energy into mechanical energy and vice versa. For this reason, electromechanical converters may be used as sensors, actuators and/or generators. An example of this can be found in the systems mentioned in WO-A 2001/006575, which use pre-tensioned polymers.

One class of converters of this kind is based on electrically active polymers. It is a constant goal to raise the properties of electrically active polymers, in particular electrical resistance and rupture resistance. At the same time, however, the mechanics of the polymers should make them suited to use in electromechanical converters.

One way of raising the dielectric constant is to add certain extenders. For example, WO-A 2008/095621 describes polyurethane compositions which are filled with carbon black which at least comprise polyether urethanes into which polyol components are incorporated and which are based on 50-100 wt. % of polyalkylene oxides produced by DMC catalysis, in particular polypropylene oxides, and 0-50 wt. % of polyols free from catalyst residues, in particular those polyols that have been purified by distillation or recrystallisation, or that have not been produced by ring-opening polymerisation of oxygen heterocycles. The polyurethane compositions further contain 0.1-30 wt. % of carbon black.

Energy converters comprising film-forming water-based polyurethane dispersions are disclosed in WO-A 2009/074192. There too, the high dielectric constants and the good mechanical properties of the polyurethane films that are obtained are emphasised.

US-A 5977685, JP-A 07240544, JP-A 06085339 and JP-B 3026043 disclose electromechanical converters containing a polyurethane elastomer made from macromolecular polyols, organic polyisocyanates and compounds for chain extension, in which the molar ratio of the NCO groups of the polyisocyanate to the OH groups of the polyol is in the range from 1.5 to 9.

However, there is still a need for electromechanical converters with dielectric elastomers which have at the same time high electrical resistance and high breakdown field strength values in order to achieve even higher degrees of efficiency in the converters. Moreover, the properties of flexibility and reversible deformability of the dielectric elastomers must be further improved.

According to the invention, an electromechanical converter is therefore proposed which includes a dielectric elastomer which is in contact with a first electrode and a second electrode, in which the dielectric elastomer includes a polyurethane polymer. The converter according to the invention is characterised in that the polyurethane polymer can be obtained by reacting

A) trifunctional polyisocyanate having a biuret and/or isocyanurate structure with

B) a compound having at least two isocyanate-reactive groups,

in which the compound having at least two isocyanate-reactive groups B) includes polyester and/or polycarbonate units, and

in which the molar ratios of isocyanate groups in A) to isocyanate-reactive groups in B) are from 0.8:1.0 to 1.3:1.0, preferably 0.9:1.0 to 1.2:1.0. Surprisingly, it has been found that the polyurethane polymers provided in the electromechanical converter according to the invention have particularly high electrical resistance values in combination with high breakdown field strength values. At the same time, the polyurethanes are present as soft elastomers. This combination of properties results in advantageous use in electromechanical converters.

When a mechanical load is exerted on a converter of this kind, the converter is deformed, for example along its thickness and its surface, and a strong electrical signal can be detected at the electrodes. This converts mechanical energy to electrical energy. Consequently, the converter according to the invention can be used as a generator and as a sensor.

On the other hand, it is also possible for the converter according to the invention to serve as an actuator by utilising the opposite effect, that of converting electrical energy to mechanical energy.

Suitable electrodes are in principle any materials that have sufficiently high electrical conductivity and can advantageously follow the extension of the dielectric elastomer. For example, the electrodes may be constructed from an electrically conductive polymer, conductive ink, or carbon black.

Dielectric elastomers, in the context of the present invention, are those elastomers which can change their shape as a result of the application of an electrical field. In the case of elastomer films the thickness may for example be reduced at the same time as a lengthwise extension of the film in the surface direction.

The thickness of the dielectric elastomer film is preferably ≧1 μm to ≦500 μm, more preferably ≧10 μm to ≦150 μm. It may be of one-piece or multiple-piece construction. For example, a multiple-piece film may be obtained by laminating individual films on top of one another.

In addition to the polyurethane polymer provided according to the invention, the dielectric elastomer may also contain further components. Such components are for example crosslinking agents, thickening agents, co-solvents, thixotropic agents, stabilisers, anti-oxidants, light stabilisers, emulsifiers, surfactants, adhesives, plasticisers, water repellents, pigments, extenders and levelling agents.

Extenders in the elastomer may for example regulate the dielectric constant of the polymer. Examples of these are ceramic extenders, in particular barium titanate, titanium dioxide and piezoelectric ceramics such as quartz or lead zirconium titanate, and organic extenders, in particular those having a high capacity for electrical polarisation, for example phthalocyanines.

In addition, it is also possible to achieve a high dielectric constant by incorporating electrically conductive extenders below the percolation threshold. Examples of these are carbon black, graphite, single-walled or multi-walled carbon nanotubes, electrically conductive polymers such as polythiophenes, polyanilines or polypyrroles or mixtures thereof. Of particular interest in this context are those carbon black types which have surface passivation and which thus raise the dielectric constant at low concentrations below the percolation threshold and yet do not result in an increase in the conductivity of the polymer.

The polyurethane polymer which is provided in the electromechanical converter according to the invention can be obtained by reacting a trifunctional polyisocyanate having a biuret and/or isocyanurate structure with a compound B) having at least two isocyanate-reactive groups, in which the molar ratios of isocyanate groups in A) to isocyanate-reactive groups in B) are from 0.8:1.0 to 1.3:1.0, preferably 0.9:1.0 to 1.2:1.0. Here, B) includes the polyester and/or polycarbonate units.

The polyester and/or polycarbonate units in the polyurethane polymer can be obtained for example by reacting polyisocyanates A) with polyester polyols and/or polycarbonate polyols. Suitable trifunctional polyisocyanates having a biuret and/or isocyanurate structure A) are for example and according to the invention those compounds based on 1,4-butylene diisocyanate, 1,6-hexamethylene diisocyanate (HDI), isophorone diisocyanate (IPDI), 2,2,4 and/or 2,4,4-trimethylhexamethylene diisocyanate, isomeric bis-(4.4′-isocyanatocyclohexyl)methanes or mixtures thereof with any isomer content, 1,4-cyclohexylene diisocyanate, 4-isocyanatomethyl-1,8-octane diisocyanate (nonane triisocyanate), 1,4-phenylene diisocyanate, 2,4- and/or 2,6-toluylene diisocyanate, 1,5-naphthylene diisocyanate, 2,2′- and/or 2,4′- and/or 4,4′-diphenylmethane diisocyanate, 1,3- and/or 1,4-bis-(2-isocyanato-prop-2-yl)-benzene (TMXDI), 1,3-bis(isocyanatomethyl)benzene (XDI), alkyl-2,6-diisocyanatohexanoates (lysine diisocyanates) with alkyl groups having from 1 to 8 carbon atoms and mixtures thereof. It is preferable to use components based on 1,6-hexamethylene diisocyanate (HDI), isophorone diisocyanate (IPDI), bis-(4,4′-isocyanatocyclohexyl)methane, toluylene diisocyanate and/or diphenylmethane diisocyanate.

Within the context of the present invention, component B) may in principle be a compound having at least two isocyanate-reactive groups, preferably amino and/or hydroxyl groups, particularly preferably hydroxyl groups. For example, component B) may be a polyol having at least two isocyanate-reactive hydroxyl groups.

Polyester components which may be used as component B) are the polycondensates, known per se, of di- and where appropriate tri- and tetraols and di- and where appropriate tri- and tetracarboxylic acids or hydroxycarboxylic acids or lactones. Instead of the free polycarboxylic acids, it is also possible to use the corresponding polycarboxylic anhydrides or corresponding polycarboxylates of lower alcohols to make the polyesters. Preferably, polyester polyols having number average molecular weights Mₙ of from 400 to 8000 g/mol, particularly preferably from 600 to 3000 g/mol, are used.

Examples of suitable diols for making the polyester polyols are ethylene glycol, butylene glycol, diethylene glycol, triethylene glycol, polyalkylene glycols such as polyethylene glycol, and further 1,2-propane diol, 1,3-propane diol, butane diol(1,3), butane diol(1,4), hexane diol(1,6) and isomers, neopentyl glycol or neopentyl glycol hydroxypivalate, in which hexane diol(1,6) and isomers, butane diol(1,4), neopentyl glycol and neopentyl glycol hydroxypivalate are preferred. In addition, it is also possible to use polyols such as trimethylol propane, glycerine, erythritol, pentaerythritol, trimethylol benzene or tris hydroxyethyl isocyanurate.

Possible dicarboxylic acids for making the polyester polyols are for example phthalic acid, isophthalic acid, terephthalic acid, tetrahydrophthalic acid, hexahydrophthalic acid, cyclohexane dicarboxylic acid, adipic acid, azelaic acid, sebacic acid, glutaric acid, tetrachlorophthalic acid, maleic acid, fumaric acid, itaconic acid, malonic acid, suberic acid, 2-methyl succinic acid, 3,3-diethyl glutaric acid and/or 2,2-dimethyl succinic acid. The corresponding anhydrides may also be used as the source of the acid.

If the average functionality of the polyol to undergo esterification is >2, it is also possible to use monocarboxylic acids such as benzoic acid and hexane carboxylic acid in addition.

Preferred acids for making the polyester polyols are aliphatic and/or aromatic acids of the type mentioned above. Particularly preferred are adipic acid, isophthalic acid and phthalic acid.

Hydroxy carboxylic acids which may be used in addition as reactants in making a polyester polyol with terminal hydroxyl groups are for example hydroxycaproic acid, hydroxybutyric acid, hydroxydecanoic acid, hydroxystearic acid and similar. Suitable lactones are caprolactone, butyrolactone and homologues. Caprolactone is preferred.

Polycarbonate components which may be used as component B) are polycarbonates—preferably polycarbonate diols—having hydroxyl groups, having number average molecular weights Mₙ of from 400 to 8000 g/mol, particularly preferably from 600 to 3000 g/mol. These may be obtained by reacting carbon dioxide, carboxylic acid derivatives, such as diphenyl carbonate, dimethyl carbonate or phosgene, with polyols, preferably diols.

Examples of such diols are ethylene glycol, 1,2- and 1,3-propane diol, 1,3- and 1,4-butane diol, 1,6-hexane diol, 1,8-octane diol, neopentyl glycol, 1,4-bishydroxymethyl cyclohexane, 2-methyl-1,3-propane diol, 2,2,4-trimethylpentane diol-1,3, dipropylene glycol, polypropylene glycols, dibutylene glycol, polybutylene glycols, bisphenol A and lactone-modified diols of the type mentioned above.

Preferably, the diol component contains from 40 to 100 wt. % of hexane diol, with 1,6-hexane diol and/or hexane diol derivatives being preferred. Hexane diol derivatives of this kind are based on hexane diol and include, in addition to terminal OH groups, ester or ether groups. Derivatives of this kind may be obtained by reacting hexane diol with excess caprolactone or by etherifying hexane diol with itself to give di- or trihexylene glycol.

Instead of or in addition to pure polycarbonate diols, polyether polycarbonate diols may also be used. Polycarbonates having hydroxyl groups are preferably straight-chain in structure.

Within the context of the present invention, the term “a” used in connection with components A) and B) is not used to indicate numerical values but as the indefinite article.

In an embodiment of the electromechanical converter according to the invention, the polyurethane polymer may be obtained by reacting a trifunctional polyisocyanate having a biuret and/or isocyanurate structure A) with a polyester and/or polycarbonate polyol B). Preferably, the trifunctional polyisocyanate having a biuret and/or isocyanurate structure is in each case based on an aliphatic diisocyanate, particularly preferably in each case hexamethylene diisocyanate.

In a further embodiment of the electromechanical converter according to the invention, the proportion of polyester and/or polycarbonate units in the polyurethane polymer is from ≧20 wt. % to ≦90 wt. %. Preferably, this proportion is from ≧25 wt. % to ≦80 wt. %, particularly preferably from ≧30 wt. % to ≦50 wt. %.

In a further embodiment of the electromechanical converter according to the invention, the polyurethane polymer has a modulus of elasticity at an extension of 50% of from ≧0.1 MPa to ≦15 MPa. The modulus is in this case determined to DIN EN 150 672 1-1, and may also be ≧0.2 MPa to ≦5 MPa. Further, the polyurethane polymer may have a maximum tension of ≧0.2 MPa, in particular from ≧0.4 MPa to ≦50 MPa, and a maximum extension of ≧250%, in particular ≧350%. Moreover, the polymer element according to the invention may have, in the range of extension in use of from ≧50% to ≦200%, a tension of from ≧0.1 MPa to ≦1 MPa, for example from ≧0.15 MPa to ≦0.8 MPa, particularly from ≧0.2 MPa to ≦0.3 MPa (determined to DIN 53504).

The present invention further relates to a method for producing an electromechanical converter, including the following steps:
1) preparation of a first electrode and a second electrode;
2) preparation of a dielectric elastomer, in which the dielectric elastomer includes a polyurethane polymer, and the polyurethane polymer may be obtained by reacting
   A) trifunctional polyisocyanate having a biuret and/or isocyanurate structure with
   B) a compound having at least two isocyanate-reactive groups,
   in which the compound having at least two isocyanate-reactive groups B) includes polyester and/or polycarbonate units, and
   in which the molar ratios of isocyanate groups in A) to isocyanate-reactive groups in B) are from 0.8:1.0 to 1.3:1.0, preferably 0.9:1.0 to 1.2:1.0;
3) disposition of the dielectric elastomer between the first electrode and the second electrode.

Details on the polyurethane polymer, including the embodiments thereof, have already been described in connection with the device according to the invention. To avoid needless repetition, the reader is referred to this in relation to the method.

In the method according to the invention, the dielectric elastomer is preferably prepared by applying the reaction mixture that gives the polyurethane polymer to the first and/or second electrode. The advantage of this approach is in particular the fact that the curing elastomer can establish good adhesion to the electrodes.

The reaction mixture may be applied for example by being knife coated, brushed, poured, spin coated, sprayed or extruded.

Preferably, once the reaction mixture has been applied the system is dried and/or tempered. The drying/tempering can in this case be performed in a temperature range of from 0° C. to 200° C., for example for from 0.1 min to 48 h, in particular for from 6 h to 18 h; drying/tempering for a duration of from 15 min to 30 min in a temperature range of from 60° C. to 120° C. is particularly preferred.

The present invention further relates to the use of a dielectric elastomer as an actuator, sensor and/or generator in an electromechanical converter, in which the dielectric elastomer includes a polyurethane polymer and the polyurethane polymer may be obtained by reacting

A) trifunctional polyisocyanate having a biuret and/or isocyanurate structure with

B) a compound having at least two isocyanate-reactive groups,

in which the compound having at least two isocyanate-reactive groups B) includes polyester and/or polycarbonate units, and

in which the molar ratios of isocyanate groups in A) to isocyanate-reactive groups in B) are from 0.8:1.0 to 1.3:1.0, preferably 0.9:1 to 1.2:1.

Details on the polyurethane polymer, including the embodiments thereof, have already been described in connection with the device according to the invention. To avoid needless repetition, the reader is referred thereto in relation to the use thereof.

Use may apply in a range of extremely varied applications in the electromechanical and electroacoustic sector, in particular in the sector of energy recovery from mechanical waves (energy harvesting), acoustics, ultrasound, medical diagnostics, scanning acoustic microscopy, mechanical sensor technology, in particular sensor technology relating to pressure, force and/or expansion, robotics and/or communications technology. Typical examples of this are pressure sensors, electroacoustic converters, microphones, loudspeakers, vibration transducers, light deflectors, diaphragms, modulators for glass fibre optics, pyroelectric detectors, capacitors and control systems and “intelligent” floors, and systems for converting the energy of water waves, in particular sea wave energy, into electrical energy.

The invention further relates to an electrical and/or electronic device, including an electromechanical converter according to the invention.

### EXAMPLES

Unless indicated otherwise, all percentage figures refer to weight and all analytical measurements were taken at temperatures of 23° C. NCO contents were determined by volume, unless explicitly stated otherwise, to DIN-EN ISO 11909.

The viscosities stated were determined by means of a rotational method of viscometry to DIN 53019 at 23° C. using a rotational viscometer from Anton Paar Germany GmbH.

The tensile tests were performed using a tension testing machine from Zwick, model number 1455, fitted with a load cell of 1 kN for the entire measuring range to DIN 53 504 with a traction speed of 50 mm/min. S2 tension bars were used as the test pieces. Each measurement was performed on three test pieces which had been prepared in the same way, and the average of the data obtained was used for assessment. The tension in [MPa] at an elongation of 50% was determined.

The electrical resistance was determined by means of a laboratory setup from Keithley Instruments, model No 6517 A and 8009, to ASTM D 257 (a method for determining the insulation resistance of materials).

The breakdown field strength was determined to ASTM D 149-97a using a high-voltage source, the hypotMAX model from Associated Research Inc., and a sample holder of the tester's own design. The sample holder makes contact with the polymer samples, which are of uniform thickness, with only a small initial mechanical load and prevents the user from coming into contact with the potential. With this construction the polymer film, which is not pre-tensioned, was put under static load with increasing voltage until the film underwent electrical breakdown. The measurement result is the voltage that was achieved at breakdown in relation to the thickness of the polymer film, in [V/μm]. Five measurements were performed on each film and the average established.

Substances and Abbreviations Used:
Desmodur® N 100: a trifunctional biuret based on hexamethylene diisocyanate (HDI biuret), NCO content 21.95±0.3% (to DIN EN ISO 11 909), viscosity at 23° C. 9630±750 mPa·s, Bayer Material Science AG, Leverkusen, Germany.
Desmodur® N 3300: a trifunctional isocyanurate based on hexamethylene diisocyanate (HDI trimer), NCO content 21.8±0.3% (to DIN EN ISO 11 909), viscosity at 23° C. 3000±750 mPa·s, Bayer Material Science AG, Leverkusen, Germany.
Desmodur® 44M 4.4′-methylene diphenyl diisocyanate, Bayer Material Science AG, Leverkusen, Germany.
Desmodur® XP 2599 an aliphatic prepolymer containing ether groups and based on HDI, Bayer Material Science AG, Leverkusen, Germany.
Terathane® 2000 Polytetramethylene ether glycol with Mₙ=2000 g/mol, INVISTA Resins & Fibers, Hattersheim am Main, Germany.
Terathane® 2900 Polytetramethylene ether glycol with Mₙ=2900 g/mol, INVISTA Resins & Fibers, Hattersheim am Main, Germany.
Terathane® 650 Polytetramethylene ether glycol with Mₙ=650 g/mol, INVISTA Resins & Fibers, Hattersheim am Main, Germany.
PolyTHF® 2000 a difunctional polytetraethylene glycol polyether with Mₙ=2000 g/mol, BASF SE, Ludwigshafen, Germany.
PolyTHF® 2900 a difunctional polytetraethylene glycol polyether with Mₙ=2900 g/mol, BASF SE, Ludwigshafen, Germany.
Arcol® PPG 2000 a difunctional polypropylene glycol polyether with Mₙ=2000 g/mol, Bayer Material Science AG, Leverkusen, Germany.
Acclaim® 6320 a trifunctional polypropylene oxide polyethylene oxide polyether with Mₙ=6000 g/mol and a proportion of ethylene oxide units of 20 wt. %, Bayer Material Science AG, Leverkusen, Germany.
Acclaim® 6300 a trifunctional polypropylene oxide polyether with Mₙ=6000 g/mol, Bayer Material Science AG, Leverkusen, Germany.
Desmophen® 670 a polyester with a low degree of branching containing hydroxyl groups, hydroxyl content 4.3±0.4% (DIN 53 240/2), Bayer Material Science AG, Leverkusen, Germany.
Desmophen® P 200 H/DS a straight-chain polyester containing hydroxyl groups, Bayer Material Science AG, Leverkusen, Germany.
Desmophen® C 2200 a straight-chain aliphatic polycarbonate diol having terminal hydroxyl groups and a molecular weight of approximately 2000 g/mol, Bayer Material Science AG, Leverkusen, Germany.
Desmophen® C 2201 a polyester of hexanediol-dimethyl carbonate with a molecular weight of approximately 2000 g/mol, Bayer Material Science AG, Leverkusen, Germany.
Desmophen®2001KS a polyester polyol with a molecular weight of approximately 2000 g/mol polyethylene/polybutylene adipate diol, Bayer Material Science AG, Leverkusen, Germany.
Mesamoll® an alkyl sulfonic acid ester of phenol, Lanxess Deutschland GmbH, Leverkusen, Germany
DBTDL dibutyl tin dilaurate, E. Merck KGaA, Darmstadt, Germany.
Desmorapid® SO tin(II)-2-ethyl hexanoate, Bayer Material Science AG, Leverkusen, Germany
Irganox® 1076 octadecyl-3-(3,5-di-tert.butyl-4-hydroxyphenyl)-propionate, Ciba Specialty Chemicals Inc., Basle, Switzerland
Fascat® 4102 butyl tin-tris-2-ethyl hexanoate, Arkema Inc. Philadelphia, USA

### Example 1

Preparation of adiisocyanate-functional polyisocyanate prepolymer 1300 g of hexamethylene-1,6-diisocyanate (HDI) and 0.27 g of dibutyl phosphate were put into a 4-litre 4-necked flask with stirring. 1456 g of Arcol® PPG 2000 was added at 80° C. within 3 hours and stirring was continued for 1 hour at the same temperature. Then thin-film distillation was carried out at 130° C. and 0.1 torr to distil off excess HDI. The NCO prepolymer which was obtained had an NCO content of 3.27% and a viscosity of 1680 mPas (25° C.).

### Example 2

Preparation of a tetraisocyanate-functional polyisocyanate prepolymer 1000 g of hexamethylene-1,6-diisocyanate (HDI) and 0.15 g of zirconium octoate were put into a 4-litre 4-necked flask with stirring. 1000 g of PolyTHF® 2000 was added at 80° C. and stirring was was continued for 5 hours at 115° C., with 0.15 g of zirconium octoate additionally being added on three occasions at intervals of one hour. Once this time had elapsed, 0.5 g of dibutyl phosphate was added. Then thin-film distillation was carried out at 130° C. and 0.1 torr to distil off excess HDI. The NCO prepolymer which was obtained had an NCO content of 6.18% and a viscosity of 25700 mPas (25° C.).

### Example 3

### Preparation of a Diisocyanate-Functional Polyisocyanate Prepolymer

To prepare the prepolymer, 7.15 kg of Desmodur 44M® were put into a container with agitator at a temperature of 50° C., and 45.85 kg of the polyether Acclaim 6300®, which had been brought to room temperature, was added within 15 minutes (however, optionally it is also possible for the polyether to be provided at 50° C. and then to add the isocyanate, also warmed to 50° C.).

Then the mixture was heated to 100° C. to bring about reaction and maintained at this temperature for another 7 hours. After cooling, a product having an NCO content of 2.70±0.1 wt. % and a viscosity at 70° C. of approximately 4200±600 mPas was obtained.

### Example 4 (Comparison)

Preparation of a polymer which is not for use according to the invention The raw materials used were not degassed separately. 8.65 g of a prepolymer from Example 2 and 25.0 g of Acclaim® 6320 were mixed for 1 minute with a quantity of 0.075 g of DBTDL in a polypropylene beaker, in a speed mixer operating at 3000 revolutions per minute. The still liquid reaction mixture was used to knife coat glass plates by hand with films having a wet film thickness of 1 mm. After preparation, all the films were dried in a drying cabinet overnight at 80° C. and then subjected to further tempering for 5 min at 120° C. After tempering, the films could easily be removed from the glass plate by hand.

### Example 5 (Comparison)

Preparation of a polymer which is not for use according to the invention The raw materials used were not degassed separately. 5.0 g of Desmodur® N 3300 and 20.0 g of the prepolymer from Example 1 were put into a polypropylene beaker and mixed together for 1 minute in a speed mixer operating at 3000 revolutions per minute. This mixture was then mixed for 1 minute with 38.54 g of Terathane® 2000 and a quantity of 0.01 g of DBTDL in a polypropylene beaker, in a speed mixer operating at 3000 revolutions per minute. The still liquid reaction mixture was used to knife coat glass plates by hand with films having a wet film thickness of 1 mm. After preparation, all the films were dried in a drying cabinet overnight at 80° C. and then subjected to further tempering for 5 min at 120° C. After tempering, the films could easily be removed from the glass plate by hand.

### Example 6 (Comparison)

Preparation of a polymer which is not for use according to the invention The raw materials used were not degassed separately. 19.94 g of the prepolymer from Example 2 and 30.0 g of Terathane® 2000 were mixed for 1 minute in a polypropylene beaker with a quantity of 0.03 g of DBTDL, in a speed mixer operating at 3000 revolutions per minute. The still liquid reaction mixture was used to knife coat glass plates by hand with films having a wet film thickness of 1 mm. After preparation, all the films were dried in a drying cabinet overnight at 80° C. and then subjected to further tempering for 5 min at 120° C. After tempering, the films could easily be removed from the glass plate by hand.

### Example 7 (Comparison)

Preparation of a polymer which is not for use according to the invention The raw materials used were not degassed separately. 14.27 g of the prepolymer from Example 2 was mixed for 1 minute in a polypropylene beaker with 30.0 g of Terathane® 2900 and a quantity of 0.03 g of DBTDL, in a speed mixer operating at 3000 revolutions per minute. The still liquid reaction mixture was used to knife coat glass plates by hand with films having a wet film thickness of 1 mm. After preparation, all the films were dried in a drying cabinet overnight at 80° C. and then subjected to further tempering for 5 min at 120° C. After tempering, the films could easily be removed from the glass plate by hand.

### Example 8 (Comparison)

Preparation of a polymer which is not for use according to the invention The raw materials used were not degassed separately. 1.96 g of Desmodur® N3300 was mixed for 1 minute in a polypropylene beaker with 10.0 g of Terathane® 2000 and a quantity of 0.005 g of DBTDL, in a speed mixer operating at 3000 revolutions per minute. The still liquid reaction mixture was used to knife coat glass plates by hand with films having a wet film thickness of 1 mm. After preparation, all the films were dried in a drying cabinet overnight at 80° C. and then subjected to further tempering for 5 min at 120° C. After tempering, the films could easily be removed from the glass plate by hand.

### Example 9 (Comparison)

Preparation of a polymer which is not for use according to the invention The raw materials used were not degassed separately. 6.7 g of Desmodur® N3300 was mixed for 1 minute in a polypropylene beaker with 50.0 g of Terathane® 2900 and a quantity of 0.05 g of DBTDL, in a speed mixer operating at 3000 revolutions per minute. The still liquid reaction mixture was used to knife coat glass plates by hand with films having a wet film thickness of 1 mm. After preparation, all the films were dried in a drying cabinet overnight at 80° C. and then subjected to further tempering for 5 min at 120° C. After tempering, the films could easily be removed from the glass plate by hand.

### Example 10 (Comparison)

Preparation of a polymer which is not for use according to the invention The raw materials used were not degassed separately. 25 g of Desmophen® 2001 KS was mixed in a PP beaker with 0.025 g of Irganox® 1076 at 60° C., in a speed mixer operating at 3000 revolutions per minute. Once the stabiliser had completely dissolved, 0.025 g of DBTDL was added and the mixture was mixed again for 1 minute in a speed mixer operating at 3000 revolutions per minute. Then 38.964 g of the prepolymer from Example 1 was added and the mixture was mixed again for 1 minute in a speed mixer operating at 3000 revolutions per minute.

The still liquid reaction mixture was used to knife coat a silconised film of RN 75 2SLK, using an automatic film casting instrument (type ZAA 2300, Zinser Analytik), with films having a wet film thickness of 0.25 mm. After preparation, all the films were tempered in a drying cabinet for 1 h at 100° C.

### Example 11 (Comparison)

Preparation of a polymer which is not for use according to thei nvention The raw materials used were not degassed separately. 50 g of Desmophen® C2201 was mixed with 0.05 g of Irganox® at 100° C., in a speed mixer operating at 3000 revolutions per minute. Once the stabiliser had completely dissolved, 0.5 g of Desmorapid® SO was added and the mixture was mixed again for 1 minute in a speed mixer operating at 3000 revolutions per minute. Then 34.305 g of Desmodur® XP2599 was added and the mixture was mixed again for 1 minute in a speed mixer operating at 3000 revolutions per minute.

The still liquid reaction mixture was used to knife coat a silconised film of RN 75 2SLK, using an automatic film casting instrument (type ZAA 2300, Zinser Analytik), with films having a wet film thickness of 0.25 mm. After preparation, all the films were tempered in a drying cabinet for 1 h at 100° C.

### Example 12

Preparation of a polymer for use according to the invention The raw materials used were not degassed separately. 50.0 g of Desmophen® 670 and 0.05 g of Irganox® 1076 were put into a polypropylene beaker and mixed for 1 minute in a speed mixer operating at 3000 revolutions per minute, and then heated to 60° C. Once the stabiliser, Irganox® 1076, had completely dissolved, 0.025 g of Desmorapid® SO was added and the mixture was mixed again for 1 minute in a speed mixer operating at 3000 revolutions per minute. 25.24 g of Desmodur® N 100 was added to this homogeneous mixture, which was then mixed again for 1 minute in a speed mixer operating at 3000 revolutions per minute.

The still liquid reaction mixture was used to knife coat glass plates by hand with films having a wet film thickness of 1 mm. After preparation, all the films were cured in a drying cabinet for 1 h at 100° C. After curing, the films could easily be removed from the glass plate by hand.

### Example 13

Preparation of a polymer for use according to the invention The raw materials used were not degassed separately. 50.0 g of Desmophen® C2201 and 0.05 g of Irganox® 1076 were put into a polypropylene beaker and mixed for 1 minute in a speed mixer operating at 3000 revolutions per minute, and then heated to 60° C. Once the stabiliser, Irganox® 1076, had completely dissolved, 0.01 g of DBTDL was added and the mixture was mixed again for 1 minute in a speed mixer operating at 3000 revolutions per minute. 10.79 g of Desmodur® N 3300 was added to this homogeneous mixture, which was then mixed again for 1 minute in a speed mixer operating at 3000 revolutions per minute.

The still liquid reaction mixture was used to knife coat glass plates by hand with films having a wet film thickness of 1 mm. After preparation, all the films were cured in a drying cabinet for 1 h at 100° C. After curing, the films could easily be removed from the glass plate by hand.

### Example 14

Preparation of a polymer for use according to the invention The raw materials used were not degassed separately. 50.0 g of Desmophen® C2200 and 0.05 g of Irganox® 1076 were put into a polypropylene beaker and mixed for 1 minute in a speed mixer operating at 3000 revolutions per minute, and then heated to 60° C. Once the stabiliser, Irganox® 1076, had completely dissolved, 0.15 g of Desmorapid® SO was added and the mixture was mixed again for 1 minute at 3000 revolutions per minute. 11.48 g of Desmodur® N 100 was added to this homogeneous mixture, which was mixed again for 1 minute in a speed mixer operating at 3000 revolutions per minute.

The still liquid reaction mixture was used to knife coat glass plates by hand with films having a wet film thickness of 1 mm. After preparation, all the films were cured in a drying cabinet for 1 h at 100° C. After curing, the films could easily be removed from the glass plate by hand.

### Example 15

Preparation of a polymer for use according to the invention The raw materials used were not degassed separately. 50 g of Desmophen® C2201 was mixed with 0.05 g of Irganox® 1076 at 100° C., in a speed mixer operating at 3000 revolutions per minute. Once the stabiliser had completely dissolved, 0.007 g of DBTDL was added and the mixture was mixed again for 1 minute in a speed mixer operating at 3000 revolutions per minute. Then 10.716 g of Desmodur® N100 was added and the mixture was mixed again for 1 minute in a speed mixer operating at 3000 revolutions per minute.

The still liquid reaction mixture was used to knife coat a silconised film of RN 75 2SLK, using an automatic film casting instrument (type ZAA 2300, Zinser Analytik), with films having a wet film thickness of 0.25 mm. After preparation, all the films were tempered in a drying cabinet for 1 h at 100° C.

### Example 16

Preparation of a polymer for use according to the invention The raw materials used were not degassed separately. 50.0 g of Desmophen® P 200 H/DS liquid and 0.05 g of Desmorapid® SO were put into a polypropylene beaker, heated to 60° C. and mixed for 20 minutes in a speed mixer operating at 3000 revolutions per minute. Once the stabiliser, Irganox® 1076, had completely dissolved, 0.0025 g of Fascat® 4102 was added and the mixture was mixed again for 1 minute at 3000 revolutions per minute. 10.72 g of Desmodur® N 100 was added to this homogeneous mixture, which was then mixed again for 1 minute in a speed mixer operating at 3000 revolutions per minute.

The still liquid reaction mixture was used to knife coat a silconised film of RN 75 2SLK, using an automatic film casting instrument (type ZAA 2300, Zinser Analytik), with films having a wet film thickness of 0.25 mm. After preparation, all the films were tempered in a drying cabinet for 1 h at 100° C.

### Example 17

Preparation of a polymer for use according to the invention The raw materials used were not degassed separately. 40.0 g of Desmophen® 670, 15 g of Mesamoll® and 0.05 g of Irganox® 1076 were put into a polypropylene beaker and mixed for 20 minutes in a speed mixer operating at 3000 revolutions per minute, and then heated to 60° C. Once the stabiliser, Irganox® 1076, had completely dissolved, 0.012 g of Desmorapid® SO was added and the mixture was mixed again for 1 minute at 3000 revolutions per minute. 22.18 g of Desmodur® N 100 was added to this homogeneous mixture, which was then mixed again for 1 minute in a speed mixer operating at 3000 revolutions per minute.

The still liquid reaction mixture was used to knife coat a silconised film of RN 75 2SLK, using an automatic film casting instrument (type ZAA 2300, Zinser Analytik), with films having a wet film thickness of 0.25 mm. After preparation, all the films were tempered in a drying cabinet for 1 h at 100° C.

### Example 18

Preparation of a polymer for use according to the invention 50.0 g of Desmophen® P 200 H/DS liquid, 0.05 g of Desmorapid® SO and 0.05 g of Irganox® 1076 were put into a polypropylene beaker, heated to 60° C. and mixed for 20 minutes in a speed mixer operating at 3000 revolutions per minute. Once the stabiliser, Irganox® 1076, had completely dissolved, 10.79 g of Desmodur® N 3300 was added to this homogeneous mixture, which was then mixed again for 1 minute in a speed mixer operating at 3000 revolutions per minute.

The still liquid reaction mixture was used to knife coat a silconised film of RN 75 2SLK, using an automatic film casting instrument (type ZAA 2300, Zinser Analytik), with films having a wet film thickness of 0.25 mm. After preparation, all the films were tempered in a drying cabinet for 1 h at 100° C.

The electrical resistance and the breakdown field strength of the samples were measured. The results for the examples that are not according to the invention and for the examples of polymer elements according to the invention are shown in Table 1, below. Numerical values of the volume resistivity are indicated in exponential notation. Thus, the numerical value in Example 4 corresponds to a volume resistivity of 7.46-10¹⁰ ohm cm. Table 1 also shows the moduli of elasticity of the polymers at an elongation of 50% to DIN EN 150 672 1-1.

TABLE 1
Properties of the films prepared in Examples 4 to 11
(comparison) and 12-18 (according to the invention)

| | | Volume resistivity | Breakdown field | Modulus of |
|---|---|---|---|---|
| Example | | [ohm cm] | strength [V/μm] | elasticity [MPa] |
| 4 | (comp) | 7.46E+10 | 32.0 | 0.60 |
| 5 | (comp) | 2.15E+11 | 45.8 | 0.95 |
| 6 | (comp) | 5.256E+12 | 57.0 | 1.84 |
| 7 | (comp) | 3.216E+12 | 55.4 | 1.66 |
| 8 | (comp) | 1.002E+11 | 26.1 | 1.89 |
| 9 | (comp) | 3.318E+12 | 64.0 | 1.77 |
| 10 | (comp) | 5.803E+11 | 34.1 | 0.70 |
| 11 | (comp) | 3.818E+11 | 30.3 | 0.81 |
| 12 | | 5.16E+15 | 82.5 | 10.26 |
| 13 | | 1.435E+14 | 69.4 | 2.22 |
| 14 | | 9.10E+13 | 72.4 | 1.99 |
| 15 | | 7.83E+14 | 132.6 | 2.39 |
| 16 | | 4.10E+14 | 96.7 | 1.57 |
| 17 | | 2.99E+14 | 104.0 | 2.85 |
| 18 | | 4.97E+13 | 93.6 | 1.52 |

The tests showed that the polymer according to the invention in film form has significant advantages over the prior art.

The combination of very high electrical resistance, high breakdown field strength and high modulus are particularly advantageous when the film according to the invention is used. This polymer according to the invention may advantageously be used to obtain particularly favourable degrees of efficiency in the electromechanical converters produced with it.

1. An electromechanical converter, including a dielectric elastomer which is in contact with a first electrode and a second electrode, in which the dielectric elastomer comprises a polyurethane polymer, wherein the polyurethane polymer can be obtained by reacting
A) trifunctional polyisocyanate having a biuret and/or isocyanurate structure with
B) a compound having at least two isocyanate-reactive groups,
in which the compound having at least two isocyanate-reactive groups B) includes polyester and/or polycarbonate units, and
in which the molar ratios of isocyanate groups in A) to isocyanate-reactive groups in B) are from 0.8:1.0 to 1.3:1.0.

2. An electromechanical converter according to claim 1, in which component A) is based on an aliphatic trifunctional polyisocyanate having a biuret and/or isocyanurate structure.

3. An electromechanical converter according to claim 1 in which component A) is based on hexamethylene diisocyanate.

4. An electromechanical converter according to claims 1, wherein component B) is a polyester polyol and/or polycarbonate polyol.

5. An electromechanical converter according to claim 1, in which the proportion of polyester and/or polycarbonate units in the polyurethane polymer is from ≧20 wt. % to ≦90 wt. %.

6. An electromechanical converter according to claim 1, in which the polyurethane polymer has a modulus of elasticity at an extension of from 50% of ≧0.1 MPa to ≦15 MPa.

7. A method for producing an electromechanical converter comprising:
1) preparation of a first electrode and a second electrode;
2) preparation of a dielectric elastomer, in which the dielectric elastomer includes a polyurethane polymer, and the polyurethane polymer may be obtained by reacting
A) trifunctional polyisocyanate having a biuret and/or isocyanurate structure with
B) a compound having at least two isocyanate-reactive groups,
in which the compound having at least two isocyanate-reactive groups B) includes polyester and/or polycarbonate units, and
in which the molar ratios of isocyanate groups in A) to isocyanate-reactive groups in B) are from 0.8:1.0 to 1.3:1.0;
3) disposition of the dielectric elastomer between the first electrode and the second electrode.

8. A method according to claim 7, in which the dielectric elastomer is prepared by applying a reaction mixture that gives the polyurethane polymer to the first and/or second electrode.

9. An actuator, sensor and/or generator comprising a dielectric elastomer in an electromechanical converter, in which the dielectric elastomer includes a polyurethane polymer and the polyurethane polymer may be obtained by reacting
A) trifunctional polyisocyanate having a biuret and/or isocyanurate structure with
B) a compound having at least two isocyanate-reactive groups,
in which the compound having at least two isocyanate-reactive groups B) includes polyester and/or polycarbonate units, and
in which the molar ratios of isocyanate groups in A) to isocyanate-reactive groups in B) are from 0.8:1.0 to 1.3:1.0.

10. An electrical and/or electronic device, including an electromechanical converter according to claim 1.
